(19) United States
(12) Patent Application Publication
(10) Pub. No.: US 2009/0279265 A1
(43) Pub. Date: Nov. 12, 2009

(54) ELECTRONIC DEVICE MOUNTING APPARATUS AND RESONANCE SUPPRESSION METHOD THEREOF

(76) Inventor: Masaharu Imazato, Tokyo (JP)

Correspondence Address: NEC CORPORATION OF AMERICA, 6535 N. STATE HWY 161, IRVING, TX, 75039, US

(21) Appl. No.: 12/441,829

(22) PCT Filed: Aug. 27, 2007
(86) PCT No.: PCT/JP2007/066518

§ 371 Date: Mar. 18, 2009

(30) Foreign Application Priority Data
Sep. 19, 2006 (JP) 2006-252219

(51) Int. Cl. H05K 7/20

(52) U.S. Cl. 361/710

(57) ABSTRACT

A heat sink plate is mounted on an electronic device for heat radiation of the electronic device. When the fundamental wave or a harmonic wave of the clock signal of the electronic device is coincide with the size of the heat sink plate, the heat sink plate resonates and large clock signal harmonic wave noise is radiated. For suppressing the noise, a dielectric strip is mounted on an edge portion of the heat sink plate. By this dielectric strip, the resonance frequency of the heat sink plate varies so that the resonance can be suppressed.

### TECHNICAL FIELD

The present invention relates to a technique for suppressing resonance of a heat sink plate of an electronic device.

### BACKGROUND ART

An electronic device, such as an LSI and the like, which is used in information processing apparatuses such as a personal computer, a work station and the like and carries out functions like the main storage, control and calculation and is configured by a single chip, requires large electric current for achieving high speed processing. For avoiding phenomenon that the heat generated by the large current causes the temperature of the electronic device to exceed an allowable limit, a heat discharging means is installed.

FIG. 1 is the top view of an electronic device mounting apparatus having a heat discharging means which is an example for explaining a present invention, and FIG. 2 is a sectional view of an A-A′ line in FIG. 1.

As shown in FIG. 1 and FIG. 2, an electronic device 2 which generates a large amount of heat, such as an LSI and the like, is mounted on a printed circuit board 1, and a heat sink plate 3 for discharging the heat generated by an operation of the electronic device 2 is placed on the electronic device 2.

When the electronic device 2 is operated in accordance with a clock signal, the clock signal has a fundamental wave and higher harmonic waves having integer times thereof, and the clock signal harmonic waves are transmitted to the printed circuit board 1 and the heat sink plate 3 as noise. The clock signal harmonic wave noise, which is transmitted from the electronic device 2 to the heat sink plate 3 through electrostatic coupling, are radiated from the heat sink plate 3.

FIG. 3 shows a perspective view of the heat sink plate 3. As shown in FIG. 3, the planar shape of the heat sink plate 3 has a rectangular shape. Then, the size of one side is represented by “a,” and the size of the other side is represented by “b.” FIG. 4 shows a side view in the direction from which the side having the size “a” is shown. In FIG. 4, at the frequency whose half-wavelength is coincident with the size “a” of the one side, the voltage waveform has the maximum value V0 at both ends of the heat sink plate, as indicated by a solid line. The current waveform has the maximum value IO at the center of the heat sink plate as shown by a dashed line. This state is referred to as the resonance at the half-wavelength.

When the clock signal harmonic wave noise is emitted through the heat sink plate 3, if the ½ wavelength of the fundamental wave frequency of the clock signal or a harmonic frequency thereof coincides with the size “a” of the heat sink plate 3, it is resonated at the coincident frequency, and the emission noise level is increased.

Then, a technique is proposed in which the size “a” of one side of the heat sink plate 3 is set to the size which does not coincide with the half-wavelength of a signal frequency or its harmonic frequencies (for example, refer to Japanese Laid-Open Patent Application JP-P2000-156578A). However, in an actual electronic device mounting apparatus, there is a case that the size of the heat sink plate cannot be set to a suitable length only for the purpose of changing the resonance frequency. For example, in order to decrease the resonance frequency of the heat sink plate, the size “a” is desired to be longer. However, when the heat sink plate size is made longer, the area for mounting it becomes larger, which may exceed an allowable size as the electronic device mounting apparatus. In order to increase the resonance frequency of the heat sink plate, the size “a” is desired to be shorter. However, when the heat sink plate size is made shorter, the heat discharging efficiency of the heat sink plate is decreased, which may result in a problem that the heat generated by the electronic apparatus cannot be sufficiently discharged.

As a means for suppressing the resonance of a heat discharging means, a technique is proposed, in which a radio wave absorber is inserted between an electronic apparatus and a heat discharging means (for example, refer to Japanese Laid-Open Patent Application JP-P2001-185893A). Moreover, Japanese Laid-Open Patent Application JP-P2000-261185A discloses a method in which both ends of a heat sink plate are connected through a conductive connector to a metal ladder, and the metal ladder is connected to an apparatus body to be short-circuited to each other.

### DISCLOSURE OF INVENTION

In order to efficiently discharge the heat generated from an electronic device by using a heat discharging means, the thermal resistance between the electronic device and the heat discharging means is required to be significantly small. However, as disclosed in Japanese Laid-Open Patent-Application JP-P 2001-185893A, when an electric wave absorber is arranged between an electronic device and a heat discharging means, because of the thermal resistance of the radio wave absorber, the heat can not be discharged sufficiently from the heat discharging means, so that the temperature may exceed the allowable limit of the electronic device. Further, when there is a constraint under which the heat sink plate cannot be connected to the circuit ground of the electronic device or the apparatus body ground, the short-circuit means of the heat sink plate described in the patent document 3 cannot be employed.

It is therefore a subject of the present invention to solve the problems of the heat discharging means as mentioned above. The object of the present invention is to reduce the high frequency noise emitted from the heat discharging means by make it possible to prevent the heat discharging means from the resonance at the clock signal frequency (or its harmonic waves), wherein at the same time, any of the following is made possible:

(1) the size of the heat discharging means does not become changed;
(2) the heat discharge characteristics does not become deteriorated; and
(3) the heat discharging means is not required to be grounded.

In order to attain the above-mentioned objects, an electronic device mounting apparatus is provided which contains: an electronic device operated in accordance with a clock signal; a heat sink member connected to the electronic device; and a resonance suppressing member made of a dielectric material and mounted on the heat sink member.

Also, in order to attain the above-mentioned objects, according to a present invention, an electronic device mounting apparatus is provided which contains: a plurality of electronic devices, each of the plurality of electronic devices is operated in accordance with a clock signal; a heat sink member commonly connected to the plurality of electronic devices; and a resonance suppressing member made of the dielectric material and mounted on the heat sink member.

Also, in order to attain the above-mentioned objects, according to a present invention, a resonance suppression method of an electronic device mounting apparatus is provided which contains: providing an electronic device to which a clock signal is transmitted and a heat sink member connected to the electronic device; and mounting the resonance suppressing member including a dielectric material on the heat sink member to prevent the heat sink member from a resonance at a frequency of the clock signal or a harmonic frequency of the clock signal.

In a present invention, a resonance suppressing member made of a dielectric material is mounted on a heat sink plate for extending an electric size to change the resonance frequency of the heat sink plate. Thus, without excessively increasing the size of the heat sink plate and without decreasing it to a degree deteriorating the heat discharge characteristics, the effective size of the heat sink plate can be made different from the half-wavelength size of the clock signal frequency transmitted through the electronic device or its harmonic frequencies. Hence, according to a present invention, it is possible to prevent the heat sink plate from resonance at the clock signal frequency of the electronic apparatus or its harmonic frequencies, and it is also possible to suppress the clock signal harmonic wave noise that is transmitted from the electronic apparatus to the heat sink plate and emitted from the heat sink plate.

### BRIEF DESCRIPTION OF DRAWINGS

FIG. 1 is the top view of the electronic device mounting apparatus in a related technique;

FIG. 2 is a sectional view of an electronic device mounting apparatus in a related technique;

FIG. 3 is a perspective view of the heat sink plate in a related technique;

FIG. 4 is a side view from a direction where the size “a” side of the heat sink plate is shown in a related technique;

FIG. 5 is the top view of an electronic device mounting apparatus according to a first exemplary embodiment of a present invention;

FIG. 6 is a sectional view of an electronic device mounting apparatus according to a first exemplary embodiment of a present invention;

FIG. 7 is a side view in a direction where the size “a” side of a heat sink plate according to a first exemplary embodiment of a present invention is shown;

FIG. 8 is a resonance characteristics view in the cases of presence and absence of a heat sink plate according to a first exemplary embodiment of a present invention;

FIG. 9 is a resonance characteristics view in the cases of presence and absence of a dielectric strip of a heat sink plate according to a first exemplary embodiment of a present invention;

FIG. 10 is a graph showing a relation between an occupation rate of the dielectric strips to the heat sink plate and a resonance frequency variation rate according to a first exemplary embodiment of a present invention;

FIG. 11 is the top view of an electronic device mounting apparatus according to a second exemplary embodiment of a present invention;

FIG. 12 is a sectional view of an electronic device mounting apparatus according to a second exemplary embodiment of a present invention;

FIG. 13 is the top view of an electronic device mounting apparatus according to a third exemplary embodiment of a present invention; and

FIG. 14 is a sectional view of an electronic device mounting apparatus according to a third exemplary embodiment of a present invention.

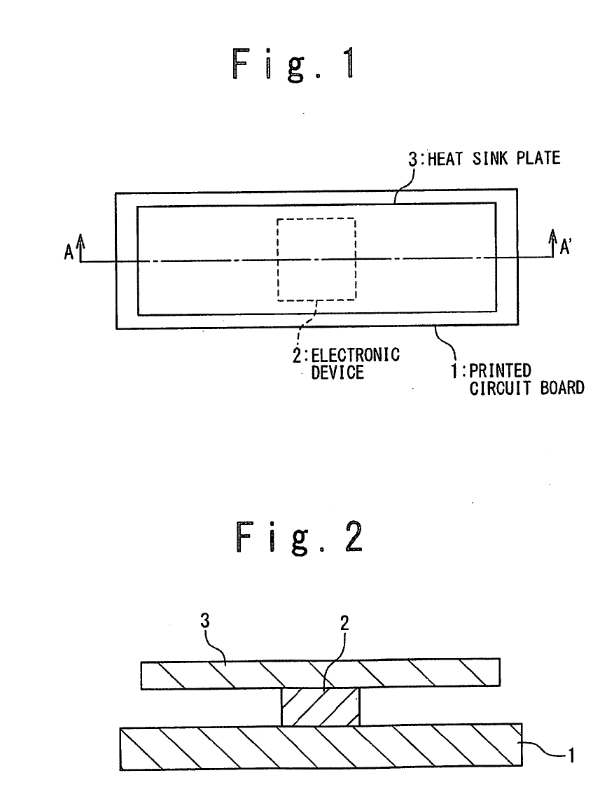

### BEST MODE FOR CARRYING OUT THE INVENTION

Exemplary embodiments of a present invention will be described below in detail with reference to the drawings.

### FIRST EXEMPLARY EMBODIMENT

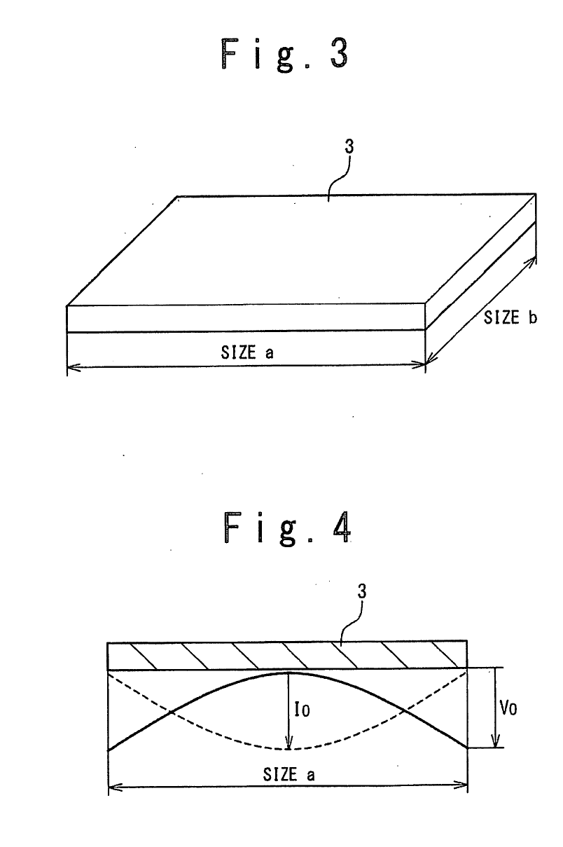

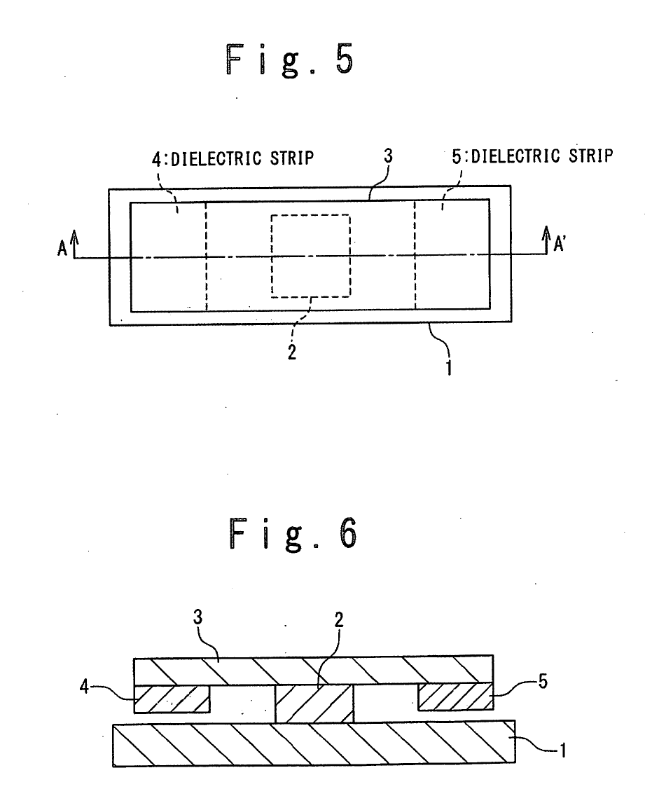

FIG. 5 is the top view of the electronic device mounting apparatus according to a first exemplary embodiment of a present invention, and FIG. 6 is the sectional view on the A-A′ line in FIG. 5. As shown in FIG. 5 and FIG. 6, the electronic device 2 is mounted on a printed circuit board 1. A heat sink plate 3 is placed on the electronic device 2, and dielectric strips 4, 5 made of dielectric material are mounted on both ends of the heat sink plate 3 on the side faced to the electronic device 2. The dielectric strips 4, 5 may be designed such that their dielectric constants are higher than 1 and metal may be included therein. As shown in FIG. 3, the size of one side of the heat sink plate 3 is represented by “a,” and the other side thereof is represented by “b.”

For mounting the dielectric strips 4, 5 on the heat sink plate 3, adhesive bonding, fastening by using a bolt and the like, and elastically pushing attachment in which a pushing means is used can be applied, however, the attachment means is not limited. In this exemplary embodiment, although the planar shapes of the dielectric strips 4, 5 are rectangular, the other shapes such as the ellipse and the like may be used. Further, in this exemplary embodiment, though the dielectric strips 4, 5 are arranged so that the ends thereof is coincide with one and other ends in the longitudinal directions of the heat sink plate, respectively, it is not necessarily required to arrange their ends to coincide with each other. However, it is preferred to arrange the dielectric strips in the positions other than the center of the heat sink plate. For example, they are desired to be in at least one of the areas other than the center area when the heat sink plate is divided into three same areas by straight lines parallel to the short side of the heat sink plate.

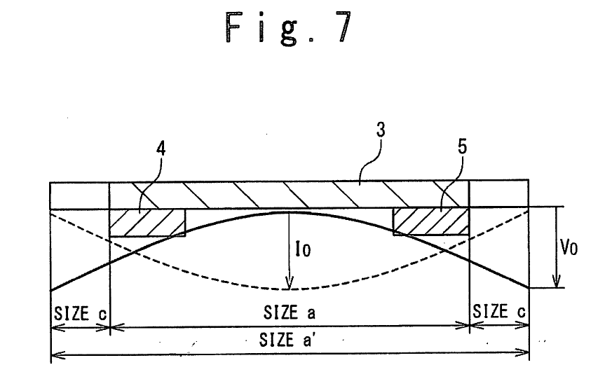

FIG. 7 shows the side view of the heat sink plate to which the dielectric strips 4, 5 are mounted on from the direction where the size “a” side of the heat sink plate is shown. In FIG. 7, the half-wavelength of a clock signal harmonic frequency and the size “a” of the heat sink plate 3 are coincident to each other. However, because of the dielectric strips 4, 5 mounted on both the ends of the heat sink plate 3, the electrical size of the heat sink plate 3 is extended by the size “c,” respectively, to become the size “a′” represented by the following:

Size a′=a+2c.

Consequently, the electrical size “a′” of the heat sink plate and the half-wavelength of the clock signal harmonic frequency become not coincident to each other.

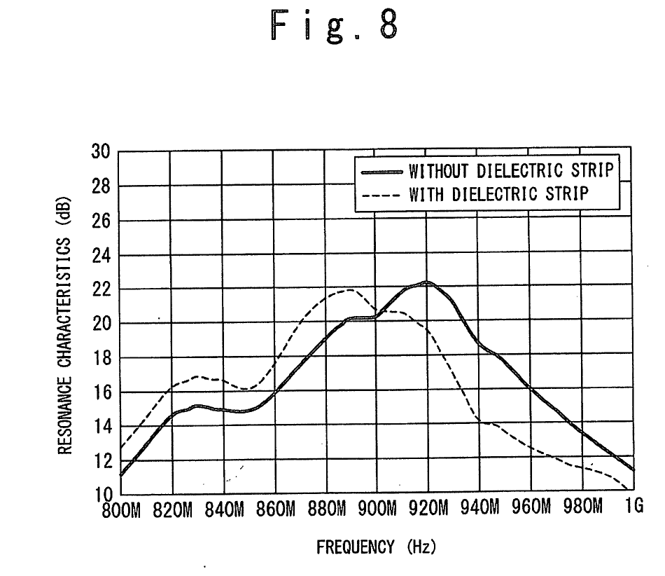

FIG. 8 shows the resonance characteristics of the heat sink plate in the cases of the presence and absence of the dielectric strips having the dielectric constant of about 10 and being mounted on both ends of the heat sink plate respectively. The sizes of the heat sink plate and the dielectric strip are 150 mm×60 mm and 10 mm×60 mm, respectively. The measurement is carried out by placing a high frequency signal source at the position of the electronic apparatus and observing the electric wave value received by an antenna placed at an interval of a predetermined distance. In FIG. 8, the horizontal axis indicates the frequency of the high frequency signal source, and the vertical axis indicates the signal intensity observed by the antenna, respectively. Here, the reference value (0 dB) of the vertical axis is the received electric wave value when the heat sink plate does not exist. The solid line indicates the resonance characteristics of the heat sink plate when the dielectric strip is not mounted on. In this case, the resonance frequency is located at the maximum resonance level position on the solid line and indicates about 920 MHz. The dashed line indicates the resonance characteristics in the case where the dielectric materials are mounted on both ends of the heat sink plate. The maximum resonance level position of the dashed line indicates about 890 MHz and indicates that the resonance frequency is reduced from 920 MHz to 890 MHz (the variation rate of about 4%). It can be recognized that the resonance frequency of the heat sink plate is reduced by mounting the dielectric strips on the heat sink plate.

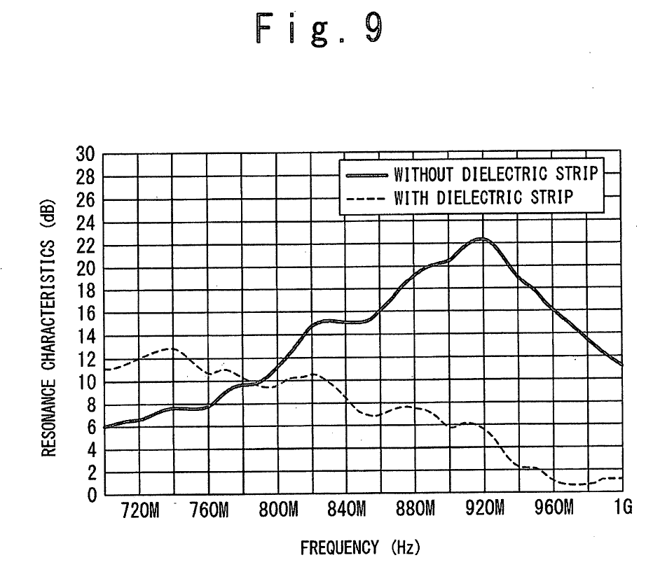

FIG. 9 shows the resonance characteristics when the size of the dielectric strip mounted on the heat sink plate is longer than that of the case shown in FIG. 8. The sizes of the heat sink plate and the dielectric strip are 150 mm×60 mm and 50 mm×60 mm, respectively. In FIG. 9, when the dielectric strip is not mounted on, the resonance frequency of the heat sink plate is about 920 MHz. When the dielectric strip is mounted on, the resonance frequency is about 740 MHz (the variation rate of about 20%). In this case, the resonance frequency can be further decreased by increasing the size of the dielectric strip.

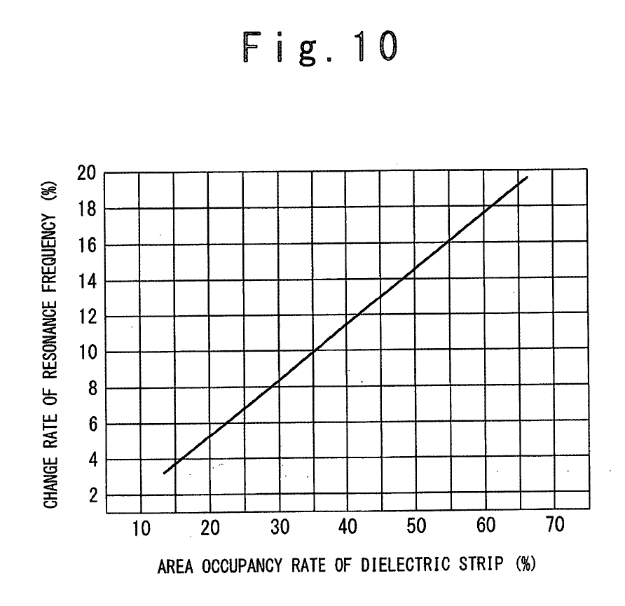

FIG. 10 is a graph showing the relation between: the occupation rate of the dielectric strips mounted on the heat sink plate to the heat sink plate size; and the resonance frequency variation rate of the heat sink plate. In FIG. 10, as the area occupancy rate of the dielectric strips mounted on the heat sink plate becomes larger, the change rate of resonance frequency can be made larger. Thus, by selecting the size of the dielectric strip, it is possible to change the resonance frequency to an appropriate value. Or, by preparing dielectric strips of predetermined sizes and determining the number of the dielectric strips to be mounted on, it is possible to adjust the resonance frequency to be an appropriate value.

Similarly, by making the thickness of the dielectric strip thicker, it is also possible to increase the variation rate of the resonance frequency. Also, by using the dielectric strip whose dielectric constant is higher, it is possible to increase the variation rate of the resonance frequency. Thus, in a resonance suppressing method of an electronic device mounting apparatus according to a present invention, any one of: the area occupation rate between the dielectric strips attached to the heat sink plate and the heat sink plate; the thickness of the dielectric strip; and the dielectric constant of the dielectric strip, or a plurality of parameters among them is selected. By this selection, the resonance frequency is varied to be different from the clock signal frequency or its harmonic frequencies. As a result, the high frequency noise level radiated through the heat sink plate can be reduced.

### SECOND EXEMPLARY EMBODIMENT

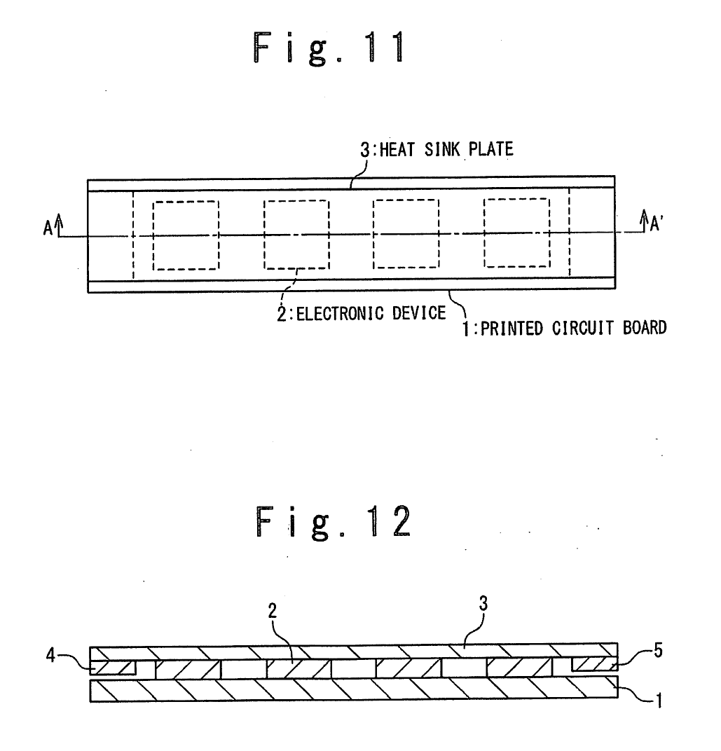

FIG. 11 is the top view of an electronic device mounting apparatus according to a second exemplary embodiment of a present invention in which a plurality of electronic apparatuses are mounted and FIG. 12 is the sectional view of the A-A′ line in FIG. 11. As shown in FIG. 11 and FIG. 12, the plurality of electronic apparatuses 2 are mounted on a printed circuit board 1. A heat sink plate 3 is placed on the electronic apparatuses 2, and the dielectric strips 4, 5 are mounted on both the ends of the heat sink plate 3 on the side faced to the electronic apparatuses 2.

The side view from a direction where the size “a” side of the heat sink plate to which the dielectric strips 4, 5 are mounted on is shown in FIG. 7, similarly to the case of a first exemplary embodiment. As shown in FIG. 7, the half-wavelength of the clock signal harmonic wave noise frequency and the size “a” of the heat sink plate 3 are coincident to each other. However, since the dielectric strips 4, 5 are attached to both the ends of the heat sink plate 3 respectively, the electrical size of the heat sink plate 3 is extended by the size “c” at the respective sides, and it become the size “a′,” which is represented by the following equation:

Size a′=a+2c.

As a result, the electrical size “a′” of the heat sink plate placed on the plurality of electronic apparatuses can be made different from the half-wavelength of the clock signal harmonic wave noise frequency.

### THIRD EXEMPLARY EMBODIMENT

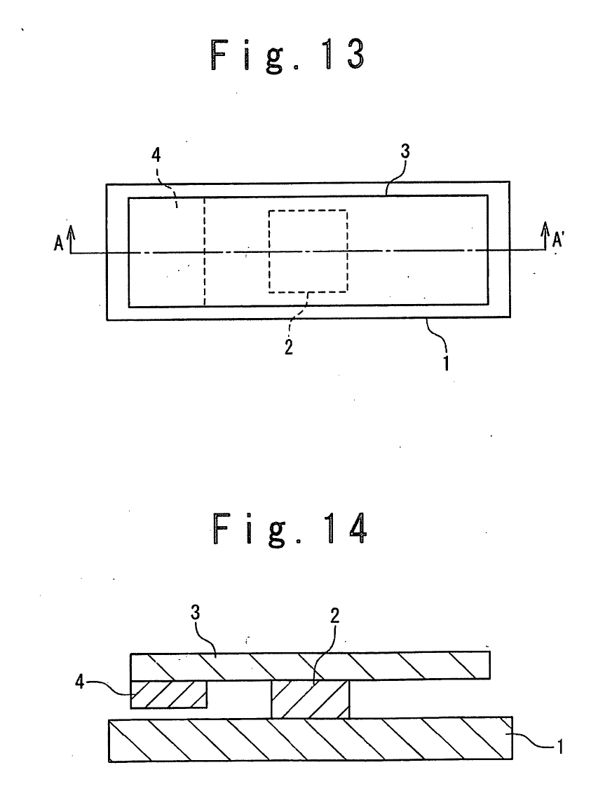

FIG. 13 is the top view of an electronic device mounting apparatus in which a dielectric strip according to a third exemplary embodiment of a present invention is mounted to only one end of the heat sink plate, and FIG. 14 is a sectional view on the A-A′ line in FIG. 9. As shown in FIG. 13 and FIG. 14, an electronic device 2 is mounted on a printed circuit board 1. A heat sink plate 3 is placed on the electronic apparatuses 2, and the dielectric strip 4 is mounted on one end of the heat sink plate 3 on the side faced to the electronic apparatuses 2.

Also in this exemplary embodiment, the half-wavelength of the clock signal harmonic wave noise frequency and the size of the heat sink plate 3 are coincident to each other. However, because of the dielectric strip mounted on one end of the heat sink plate 3, the electric size of the heat sink plate 3 is extended. As a result, the electric size of the heat sink plate placed on electronic apparatuses can be made different from the half-wavelength of the clock signal harmonic wave noise frequency.

Also, for second and third exemplary embodiments, similarly to a first exemplary embodiment, by selecting any one of: the area occupation rate between the dielectric strips mounted on the heat sink plate and the heat sink plate; the thickness of the dielectric strip; and the dielectric constant of the dielectric strip, or the plurality of parameters among them, and varying the resonance frequency, it is possible to make the resonance frequency differ from the frequency of the clock signal inside the electronic apparatus or its harmonic frequencies.

What is claimed is:

1. An electronic device mounting apparatus comprising:
an at least one electronic device operated in accordance with a clock signal;
a heat sink member connected to the at least one electronic device; and
a resonance suppressing member made of a dielectric material and mounted on the heat sink member.

2. The electronic device mounting apparatus comprising according to claim 1, wherein the at least one electronic device is a plurality of electronic devices, and
the heat sink member is commonly connected to the plurality of electronic devices.

3. The electronic device mounting apparatus according to claim 1, wherein the dielectric material is mounted on the heat sink member to prevent the heat sink member from a resonance at a frequency of the clock signal or a harmonic frequency of the clock signal.

4. The electronic device mounting apparatus according to claim 1, wherein the heat sink member and the resonance suppressing member are mounted on a same side of the at least one electronic device.

5. The electronic device mounting apparatus according to claim 1, wherein the heat sink member has a rectangular shape, and the resonance suppressing member is mounted on an area other than a center area when the heat sink member is divided into three same areas by straight lines parallel to a short side of the rectangular shape.

6. The electronic device mounting apparatus according to claim 1, wherein the resonance suppressing member is separated into a plurality of units and mounted on the heat sink member.

7. The electronic device mounting apparatus according to claim 1, wherein a planar shape of the heat sink member is a rectangular, and
the resonance suppressing member includes:
a first resonance suppressing member having a rectangular shape and arranged to coincide with one side of the heat sink member in a longitudinal direction of the heat sink member; and
a second resonance suppressing member having a rectangular shape and arranged to coincide with other side of the heat sink member in the longitudinal direction of the heat sink member.

8. A resonance suppression method of an electronic device mounting apparatus comprising:
providing an at least one electronic device operated in accordance with a clock signal and a heat sink member connected to the at least one electronic device; and
mounting a resonance suppressing member made of a dielectric material on the heat sink member to prevent the heat sink member from a resonance at a frequency of the clock signal or a harmonic frequency of the clock signal.

9. The resonance suppression method of an electronic device mounting apparatus according to claim 8, further comprising:
adjusting a resonance frequency of the heat sink member by changing an area of a planar shape of the resonance suppressing member.

10. The resonance suppression method of an electronic device mounting apparatus according to claim 8, further comprising:
adjusting a resonance frequency of the heat sink member by changing a thickness of the resonance suppressing member.

11. The resonance suppression method of an electronic device mounting apparatus according to claim 8, further comprising:
adjusting a resonance frequency of the heat sink member by changing the number of the resonance suppressing member.

12. The resonance suppression method of an electronic device mounting apparatus according to claim 8, further comprising:
adjusting a resonance frequency of the heat sink member by selecting a dielectric constant of the resonance suppressing member.
